(19) United States
(12) Patent Application Publication
(10) Pub. No.: US 2015/0228870 A1
(43) Pub. Date: Aug. 13, 2015

(54) METHOD FOR PRODUCING A LIGHT-EMITTING SEMICONDUCTOR DEVICE AND LIGHT-EMITTING SEMICONDUCTOR DEVICE

(71) Applicant: OSRAM Opto Semiconductors GmbH, Regensburg (DE)

(72) Inventors: Britta Goeoetz, Regensburg (DE); Juergen Moosburger, Lappersdorf (DE); Andreas Ploessl, Regensburg (DE); Matthias Sabathil, Regensburg (DE)

(21) Appl. No.: 14/423,432

(22) PCT Filed: Aug. 9, 2013
(86) PCT No.: PCT/EP2013/066727

§ 371 Date: Feb. 23, 2015

(30) Foreign Application Priority Data
Aug. 23, 2012 (DE) 10 2012 107 797.5

(51) Int. Cl. H01L 33/56; H01L 33/00; H01L 33/50

(52) U.S. Cl. CPC H01L 33/56; H01L 33/50; H01L 33/0066

(57) ABSTRACT

A method is specified for producing a light-emitting semiconductor component, in which method a light-emitting semiconductor layer sequence (2) with an active layer (3) that is designed to emit light during operation of the semiconductor component is provided, a wavelength conversion layer (4) containing at least one wavelength conversion material is applied on the semiconductor layer sequence (2), and a ceramic layer (5) is applied on the wavelength conversion layer (4) by means of an aerosol deposition process. A light-emitting semiconductor component is also specified.

This patent application claims priority of German patent application 102012107797.5, the disclosure content of which is hereby incorporated by reference.

A method for producing a light-emitting semiconductor device and a light-emitting semiconductor device are specified.

To generate polychromatic light, such as for example white light, by means of a light-emitting diode chip, said chip may be provided with a luminescent material which converts at least part of the light emitted by the light-emitting diode chip into light in another spectral range.

Conventionally, a luminescent powder is applied to a light-emitting diode chip by means of silicone. Since silicone is not hermetically impervious to moisture, the penetration of moisture into the silicone in such prior art light-emitting diode chip/luminescent material combinations is either accepted or additional protection is adhesively bonded on from outside, for example in the form of a glass window. Because of the moisture problem, in the case of sensitive luminescent materials given temperatures and operating currents of the light-emitting diode chips may however not be exceeded.

It is at least one object of certain embodiments to specify a method for producing a light-emitting semiconductor device. At least one further object of certain embodiments is to specify a light-emitting semiconductor device.

These objects are achieved by a subject and a method according to the independent patent claims. Advantageous embodiments and developments of the subject and of the method are defined in the dependent claims and furthermore become apparent from the following description and the drawings.

According to at least one embodiment, in a method for producing a light-emitting semiconductor device a light-emitting semiconductor layer sequence is provided with an active layer which is configured to emit light when the semiconductor device is in operation. A wavelength conversion layer with at least one wavelength conversion material is applied to the semiconductor layer sequence. Furthermore, a ceramic layer is applied to the wavelength conversion layer by means of an aerosol deposition method.

According to at least one further embodiment, a light-emitting semiconductor device comprises a light-emitting semiconductor layer sequence with an active layer which is configured to emit light when the semiconductor device is in operation. Furthermore, the light-emitting semiconductor device comprises a wavelength conversion layer with at least one wavelength conversion material on the semiconductor layer sequence. A ceramic layer applied using aerosol deposition is arranged on the wavelength conversion layer.

The features and embodiments described below apply equally to the method and to the light-emitting semiconductor device.

The semiconductor layer sequence may particularly preferably be an epitaxially grown semiconductor layer sequence. To this end, the semiconductor layer sequence may be grown on a growth substrate by means of an epitaxy method, for example metal-organic vapor phase epitaxy (MOVPE) or molecular beam epitaxy (MBE), and provided with electrical contacts. A plurality of light-emitting semiconductor chips may be provided by singulating the growth substrate with the semiconductor layer sequence grown thereon.

Furthermore, the semiconductor layer sequence may be transferred to a carrier substrate prior to singulation and the growth substrate may be thinned or removed completely. Such light-emitting semiconductor chips, which comprise a carrier substrate instead of the growth substrate as substrate, may also be called “thin-film light-emitting diode chips”.

A thin-film light-emitting diode chip is distinguished in particular by the following characteristic features:
a reflective layer is applied to or formed on a first major surface, facing the carrier substrate, of a radiation-generating semiconductor layer sequence, said reflective layer reflecting at least part of the light generated in the epitaxial semiconductor layer sequence back into it;
the semiconductor layer sequence has a thickness in the range from 20 μm or less, in particular in the range between 4 μm and 10 μm; and
the semiconductor layer sequence contains at least one semiconductor layer with at least one surface which comprises an intermixing structure, which ideally leads to an approximately ergodic distribution of the light in the semiconductor layer sequence, i.e. it exhibits scattering behavior which is as ergodically stochastic as possible.

A thin-film light-emitting diode chip is a good approximation of a Lambertian surface emitter. The basic principle of a thin-film light-emitting diode chip is described for example in the document I. Schnitzer et al., Appl. Phys. Lett. 63 (16) 18 Oct. 1993, pages 2174-2176, the disclosure content of which in this respect is hereby included by reference.

According to a further embodiment, the semiconductor layer sequence is based on a III-V compound semiconductor material. The semiconductor material is preferably a nitride compound semiconductor material such as AlₓIn_{1-x-y}Ga_{y}N or indeed a phosphide compound semiconductor material such as AlₓIn_{1-x-y}Ga_{y}P or indeed an arsenide compound semiconductor material such as AlₓIn_{1-x-y}Ga_{y}As, wherein in each case 0≦x≦1, 0≦y≦1 and x+y≦1. The semiconductor layer sequence may comprise dopants and additional constituents. For simplicity's sake, however, only the substantial constituents of the crystal lattice are indicated, i.e. Al, As, Ga, In, N or P, even if these may in part be replaced and/or supplemented by small quantities of further substances.

The active layer is in particular configured to generate light in an ultraviolet to infrared wavelength range. The active layer for example contains at least one pn junction or, preferably, one or more quantum well structures. The light generated by the active layer when in operation is preferably in a visible spectral range.

According to a further embodiment, the wavelength conversion layer comprises at least one or more wavelength conversion materials, which are suitable for absorbing at least in part the light emitted when the light-emitting semiconductor layer sequence is in operation and absorbing it as light with a wavelength range different in least in part from the light of the semiconductor layer sequence. The light emitted by the semiconductor layer sequence and the light converted by the wavelength conversion layer may in each case have one or more wavelengths and/or wavelength ranges in an infrared to ultraviolet wavelength range, preferably in a visible wavelength range. For example, the light-emitting semiconductor layer sequence may, in operation, emit light of an ultraviolet to green wavelength range, for example blue and/or green light, while the wavelength conversion layer converts at least part of this light into light of a longer-wavelength wavelength range, for example of a blue to infrared wavelength range. Through suitable selection of the materials of the light-emitting semiconductor layer sequence and in particular of the active layer and of the at least one wavelength conversion material in the wavelength conversion layer, it is thus possible to generate a desired polychromatic color appearance, for example white light, wherein in this case the light-emitting semiconductor layer sequence preferably emits blue light, which is converted by the wavelength conversion layer at least in part into infrared and/or red and/or green and/or yellow light. Alternatively, it may also be possible to configure the semiconductor device as a “full conversion light-emitting diode chip”, in which substantially all the light generated by the active region of the semiconductor layer sequence, i.e. at least 90% or at least 95% or even at least 99%, is converted by the wavelength conversion material of the wavelength conversion layer into light of another wavelength range, for example into infrared and/or red and/or green and/or yellow light.

The at least one wavelength conversion material of the wavelength conversion layer may for example comprise at least one or more of the following materials for wavelength conversion or be formed of one or more of the following materials: rare earth-doped garnets, rare earth-doped alkaline earth metal sulfides, rare earth-doped thiogallates, rare earth-doped aluminates, rare earth-doped silicates, such as orthosilicates, rare earth-doped chlorosilicates, rare earth-doped nitridosilicates, rare earth-doped oxynitrides and rare earth-doped aluminum oxynitrides, rare earth-doped silicon nitrides and rare earth-doped oxonitridoalumosilicates, rare earth-doped nitridoalumosilicates and aluminum nitrides.

At least one wavelength conversion material may take the form for example of a garnet, for instance yttrium aluminum oxide (YAG), lutetium aluminum oxide (LuAG) and/or terbium aluminum oxide (TAG), or indeed a nitride wavelength conversion material, for example a nitride wavelength conversion material based on compounds of alkaline earth metals with SiON, SiAlON, SiₓN_{y} and AlSiN.

The material for the wavelength conversion material is in further preferred embodiments for example doped with one or more of the following activators: cerium, europium, neodymium, terbium, dysprosium, erbium, praseodymium, samarium or manganese. Cerium-doped yttrium aluminum garnets, cerium-doped lutetium aluminum garnets, europium-doped orthosilicates and europium-doped nitrides may be mentioned purely by way of example as possible doped wavelength conversion materials.

Furthermore, the at least one wavelength conversion material may additionally or alternatively comprise an organic material which may be selected from a group comprising perylenes, benzopyrenes, coumarins, rhodamines and azo dyes.

The wavelength conversion layer may comprise suitable mixtures and/or combinations of the stated wavelength conversion materials.

To form the wavelength conversion layer, the at least one wavelength conversion material may be applied for example in powder form. This may proceed for example by scattering, the term “scattering” covering all possible application methods by means of which the pulverulent wavelength conversion material may be applied in particle form, i.e. for example sprinkling, blowing or spraying. Furthermore, the pulverulent wavelength conversion material may for example also be applied by means of a sedimentation method. For sedimentation of the at least one wavelength conversion material, a sedimentation solution may be provided in which the at least one pulverulent wavelength conversion material is dispersed or dissolved. After application of the sedimentation solution to the semiconductor layer sequence, the pulverulent wavelength conversion material may settle out and the liquid constituents of the sedimentation solution may be removed by evaporation or vaporization. Furthermore, it is also possible for the at least one wavelength conversion material to be applied by means of electrophoretic deposition.

In particular, the wavelength conversion material may, after application and also after completion of the semiconductor device, be present in powder form between the semiconductor layer sequence and the ceramic layer. This means that a powdery arrangement of the wavelength conversion material is discernible in the wavelength conversion layer, in comparison with a continuously contiguous layer, wherein in the pulverulent arrangement the particles of the wavelength conversion material may also be held together for example by a matrix material, a binder or by hydrogen bridge bonds.

Alternatively or in addition, at least some of the wavelength conversion layer or indeed the entire wavelength conversion layer may be provided in the form of a ceramic plate with the at least one wavelength conversion material. Such a ceramic plate may be produced for example by sintering the wavelength conversion material, wherein this may also be embedded in a ceramic matrix material. If the wavelength conversion layer takes the form of a ceramic plate, application of the ceramic layer to the wavelength conversion layer may be performed by means of the aerosol deposition method, before the ceramic plate is arranged on the semiconductor layer sequence. As an alternative, it is also possible firstly to apply the wavelength conversion material provided as a ceramic plate to the semiconductor layer sequence and thereafter to cover the ceramic plate with the ceramic layer by means of the aerosol deposition method.

According to a further embodiment, the ceramic layer is formed from a transparent ceramic material.

A ceramic material should in particular be understood to mean an oxide-containing and/or a nitride-containing material which is processed in particular in powder form, wherein here and hereinafter materials which comprise only a short-range order and no long-range order are also covered by the term “ceramic material”. Accordingly, inorganic glasses are also covered by the term “ceramic material”. A pulverulent ceramic material is understood in particular to mean a powder of a material with which a ceramic element may be produced and which may also be known as a ceramic powder.

According to a further embodiment, the ceramic layer is formed by an oxide, a nitride and/or an oxynitride, wherein the oxide, nitride and/or oxynitride comprises aluminum, silicon, titanium or zirconium or a mixture thereof. Particularly preferably, the ceramic layer may comprise Al₂O₃, AlN, SiN, SiO₂, TiO₂, ZrO₂ or a mixture or combination thereof.

According to a further embodiment, to produce the ceramic layer by means of aerosol deposition, a powder of the ceramic material, i.e. a pulverulent ceramic material or a ceramic powder, is provided for the aerosol deposition method (ADM). The size of the powder particles in the pulverulent ceramic material provided may range from the sub-micrometer range up to several micrometers. Preferably the particles of the powder have a size greater than or equal to 10 nm, particularly preferably greater than or equal to a few hundred nanometers or indeed from greater than or equal to 1 μm to up to several micrometers, preferably less than or equal to 2 μm.

The ceramic material may in particular be provided in a powder chamber which may also be known as an aerosol chamber and which has a gas feed line and a gas discharge line. By means of the gas feed line, a gas, preferably an inert gas, may be fed into the powder chamber. The gas may for example contain or consist of helium, nitrogen, oxygen, argon, air or a mixture thereof. By means of the gas, some of the particles of the powder mixture are passed in the gas via the gas discharge line into a coating chamber which preferably has a lower pressure than the powder chamber. In particular, the aerosol deposition method may be performed in the coating chamber at a temperature of less than or equal to 300° C. and preferably at room temperature, i.e. at a temperature of approximately 300 K.

The aerosol with the particles of the powder mixture passes out in the coating chamber through a nozzle and is directed by the nozzle in a jet onto the surface to be coated, which is formed at least in part by the wavelength conversion layer. Between the powder chamber and the coating chamber it is for example additionally possible to arrange one or more filters and/or a classifier for establishing suitable particle sizes. The jet with the aerosol may for example impinge on the surface to be coated in punctiform manner. Furthermore, the jet with the aerosol may also impinge on the surface to be coated in flared manner, for example fanned out in linear manner. The gas of the aerosol acts as an accelerating gas, since the particles contained in the gas stream are sprayed via said gas stream onto the surface to be coated. The nozzle and/or the surface to be coated may be movable relative to one another, in order to allow large-area application of the particles. This process may also be known as “scanning”.

In particular, the ceramic layer may be applied directly onto the wavelength conversion layer.

In comparison with sintering methods, the aerosol deposition method may be performed at markedly lower temperatures, in particular for example even at room temperature, since the energy needed to consolidate the particles of the pulverulent ceramic material, i.e. to “clump together” the particles, in order to form the ceramic layer may be provided via the kinetic energy in the gas stream, while in sintering methods the energy needed is known to be supplied by heating to high temperatures. As a result of the kinetic energy of the particles of the pulverulent ceramic material, on impact on the surface to be coated a locally very defined increase in temperature of the particles involved in the impact may be all that happens, which is however sufficient to “clump together” the particles. On impact the particles may be deformed and/or compressed and thus become smaller.

It may moreover be possible for the layer produced in this way with the clumping particles to be subsequently heated again. In such a heat treatment process the ceramic layer may be heated to a temperature which may be as high as the sintering temperature of the ceramic material. Preferably, however, the temperature to which the layer is heated is markedly below the sintering temperature.

In particular, the ceramic layer may thus form a protective layer for the wavelength conversion layer. Using the aerosol deposition method, it may in particular be possible to deposit the ceramic layer as an impervious layer, which may protect the wavelength conversion layer from harmful external influences such as for instance moisture without the semiconductor layer sequence and the wavelength conversion layer being exposed to particular thermal loads on application of the ceramic layer. At the same time, the ceramic layer may improve adhesion of the wavelength conversion layer and in particular of the at least one wavelength conversion material. The aerosol deposition method thus makes it possible to apply a transparent ceramic layer, which may enclose the conversion material particles, in particular in the case of a wavelength conversion material applied in powder form and at the same time ensure improved adhesion to the semiconductor layer sequence. In addition to protection for example from moisture, the ceramic layer may also provide protection from mechanical influences.

To achieve reliable encapsulation by the ceramic layer, it is particularly advantageous for the latter to follow as well as possible the contours of the substrate to be coated and thus to form a “conformal” layer. In particular where there are steps in the substrate to be coated, conformal deposition of the ceramic material is a requirement for hermetic encapsulation. In a directional coating method such as aerosol deposition, in which the aerosol jet from the nozzle conventionally impacts perpendicularly on the surface to be coated, perpendicular steps in the substrate to be coated may readily cause shading, such that the resultant smaller layer thickness at the side faces of such steps may jeopardize reliably impervious enclosure of the surface to be coated.

To achieve a conformal coating, i.e. a coating with a substantially constant layer thickness, using the ceramic material also at steps and side faces of the surface to be coated, the aerosol jet may be directed at different angles, preferably over a wide range of angles, onto the surface to be coated. In the case of very pronounced perpendicular or even slightly undercut steps in the surface to be coated, the necessary angular range may even extend to spraying tangentially to the main direction of extension of the surface to be coated. In particular, coating may proceed at all or at least over a very large range of all possible local surface normals. Since perpendicular incidence of the ceramic material on the surface to be coated is crucial to sufficient layer growth, a very uniform layer thickness may be achieved in this way.

According to a further embodiment, the aerosol with the pulverulent ceramic material is sprayed on in a highly fanned out particle jet onto the surface to be coated. In the case of scanning of the surface to be coated, it may consequently be possible to cover the relevant angular range. Alternatively, a less divergent aerosol jet may be used, wherein the angle between the jet and the surface is varied. Variation of the angle may for example be achieved by movement of the jet and thus of the nozzle and/or by movement of the surface to be coated and thus of the object to be coated. It is moreover also possible to combine a highly divergent jet with angular variation.

For example, the object to be coated may be rotated about the normal of the main plane of extension of the surface to be coated. This rotational motion, which may for example also be combined with a divergent aerosol jet, may be sufficient to achieve the desired conformal deposition of the ceramic material. Furthermore, the surface to be coated and thus the object to be coated may additionally be inclined in a tilting movement in such a way that the normal of the main plane of extension of the surface to be coated, which forms the axis of rotation of the previously described rotational motion, is inclined. In this case, it is also possible to achieve conformal deposition of the ceramic material with an aerosol jet which is only slightly divergent or even substantially parallel.

If the jet is sufficiently wide, it may be implemented with planetary motion, as in the case of vapor deposition methods, wherein the object to be coated rotates about the surface normal of the main plane of extension of the surface to be coated revolving on a hemisphere. In the case of less wide jet, a gyroscopic motion consisting of rotation and precession may alternatively be used. In the case of finer jets, which require scanning, the object to be coated can be inclined purposefully in accordance with the part of the surface to be coated at any given time.

In particular, knowledge of the topography to be coated may allow purposeful control, such that the aerosol jet can be oriented as far as possible parallel to all local surface normals. If a wobbling or rocking motion is superimposed on this local orientation, the topography within the surface sub-regions to be locally coated may also be taken into account. It may be particularly advantageous to this end for the surface to be coated always to be positioned eucentrically through lateral translation. In addition to particularly uniform coating, it is possible, if knowledge of the surface structure is put to purposeful use, to shorten the coating time without any reduction in quality and to apply the coating material, i.e. the ceramic material, sparingly.

In particular in the case of pulverulent configuration of the wavelength conversion material in the wavelength conversion layer, it is possible, on impact of the particles of the pulverulent ceramic material for forming the ceramic layer, to arrive at least superficially at at least partial intermixing of the material for the ceramic layer and of the wavelength conversion material. In this way, the ceramic material for the ceramic layer may penetrate into the wavelength conversion layer at least in sub-regions and form a matrix material for the wavelength conversion material.

According to a further embodiment, the ceramic layer has a thickness greater than 1 μm, preferably greater than or equal to 5 μm or indeed greater than or equal to 10 μm or indeed greater than or equal to a few tens of micrometers such as for instance greater than or equal to 20 μm or greater than or equal to 30 μm or indeed greater than or equal to 50 μm. Furthermore, the ceramic layer may have a thickness of preferably less than or equal to 200 μm or indeed preferably less than or equal to 100 μm. In particular, a thickness of a few tens of micrometers, i.e. in the range from approximately 20 μm to approximately 100 μm, may be particularly advantageous.

Application of the ceramic layer to the wavelength conversion layer may proceed at chip level and also at wafer level. Applying the ceramic layer at chip level may mean in particular that the ceramic layer is applied using aerosol deposition on a light-emitting semiconductor chip provided with the wavelength conversion layer and comprising the light-emitting semiconductor layer sequence. In this case, the light-emitting semiconductor chip is produced prior to deposition of the ceramic layer by singulation from a wafer assembly, wherein the wavelength conversion layer is applied before or after singulation, i.e. likewise at wafer level or at chip level.

Applying the ceramic layer at wafer level may in particular mean that a semiconductor layer sequence grown on a growth substrate is provided with the wavelength conversion layer, which is then covered, while still in the wafer assembly, with the ceramic layer by means of the aerosol deposition method. The wavelength conversion layer and the ceramic layer applied thereover may then be singulated together with the semiconductor layer sequence to form semiconductor chips with a wavelength conversion layer and a ceramic layer thereover.

Through suitable selection of the material of the ceramic layer, the refractive index of the ceramic layer may be adapted to the wavelength conversion layer thereunder. In this way, scattering may for example be prevented, so resulting in a higher conversion efficiency. It may furthermore also be possible for light scattering particles additionally to be embedded in the ceramic layer on application thereof. These may be added to the pulverulent starting material to form the ceramic layer and comprise a material which has a refractive index different from the ceramic material of the ceramic layer. The light scattering particles may for example comprise a material described above in relation to the ceramic layer, such that, to form the ceramic layer with light scattering particles, at least two of the above-described materials may be applied in the form of a powder mixture, wherein these materials have refractive indices which differ from one another.

It is moreover also possible for the wavelength conversion layer to comprise light scattering particles. These may be admixed in powder form with the at least one wavelength conversion material and applied together with the at least one wavelength conversion material using the above-described methods to form the wavelength conversion layer.

On application of the at least one wavelength conversion material to form the wavelength conversion layer, in particular in the case of the wavelength conversion material being applied in powder form, it must be ensured that the wavelength conversion layer is sufficiently robust not to be eroded in the subsequent aerosol deposition process for producing the ceramic layer. This may for example be achieved by pretreating the wavelength conversion material. For example the at least one wavelength conversion material may be washed in phosphoric acid prior to application, whereby hydrogen bridge bonds may be formed. In the case of application from a sedimentation solution, a small quantity of binder which remains in the wavelength conversion layer may for example be admixed with said solution. One or more of the following materials may be used as binder: silicones, ZrO₂-containing sol-gels, polysilazanes, waterglass and Al₂O₃-containing equivalents as well as organic/inorganic hybrid polymers.

According to a further embodiment, a further ceramic layer is applied to the semiconductor layer sequence, on which the wavelength conversion layer is then applied. In other words, the wavelength conversion layer may be arranged between two ceramic layers. In particular, the wavelength conversion layer may be applied directly on the further ceramic layer. The further ceramic layer, which is in particular a transparent ceramic layer, may comprise features as described above in relation to the ceramic layer applied to wavelength conversion layer. The further ceramic layer may be applied in particular directly on the semiconductor layer sequence. The further ceramic layer may in particular serve as an adhesion-promoting layer for the following wavelength conversion layer, in order to improve adhesion of the wavelength conversion layer to the semiconductor layer sequence. The ceramic layer applied to the wavelength conversion layer may, as described above, serve as a protective layer and likewise for improving adhesion.

According to a further embodiment, a plurality of ceramic layers and/or a plurality of wavelength conversion layers, but at least one of each of these, are applied alternately on one another. This may mean in particular that at least one further wavelength conversion layer and at least one further ceramic layer are applied over the wavelength conversion layer and the ceramic layer. Furthermore, for example a ceramic layer may also firstly be applied, a wavelength conversion layer on this, a ceramic layer thereover and a further wavelength conversion layer and a further ceramic layer thereover. Furthermore, more wavelength conversion layers and ceramic layers may also be applied alternately one over the other. Through such successive application of ceramic layers and wavelength conversion layers, precise color control during the application process is possible, such that the light color emitted by the finished light-emitting semiconductor device may be optimally adjusted.

The above-described features and embodiments apply equally to the further ceramic layers and the further wavelength conversion layers.

Furthermore, a material may for example be used for the ceramic layer, the coefficient of thermal expansion of which material is adapted to the coefficient of thermal expansion of the at least one wavelength conversion material of the wavelength conversion layer, such that, on heating of the semiconductor device in operation, stresses between the wavelength conversion material and the ceramic layer applied thereover may be avoided. It may in particular be advantageous for the coefficient of thermal expansion of the ceramic layer and coefficient of thermal expansion of the wavelength conversion layer to be identical or at least substantially identical, i.e. to differ from one another by at most 50% or indeed by at most 20% or indeed by at most 10%. It may alternatively or additionally be advantageous for a material to be used for the ceramic layer, the coefficient of thermal expansion of which material is adapted to the coefficient of thermal expansion of the semiconductor layer sequence and/or of a substrate for the semiconductor layer sequence, such that, on heating of the semiconductor device in operation, stresses between the semiconductor layer sequence and/or the substrate and the ceramic layer applied thereover may be avoided. In particular, the coefficients of thermal expansion of the semiconductor layer sequence and/or of a substrate of the semiconductor layer sequence and of the ceramic layer may be identical or substantially identical as stated above.

As a result of the method described here, in which a ceramic layer is applied to the wavelength conversion layer using aerosol deposition, the protective action of the ceramic layer may enable operation at higher temperatures and operating currents compared with conventional light-emitting diode chips with luminescent materials applied thereto. Furthermore, the service life of the light-emitting semiconductor device may be extended in comparison with conventional combinations of light-emitting diode chips with luminescent materials. Through flexible adaptation of the wavelength conversion layer or of the number of wavelength conversion layers between the light-emitting semiconductor layer sequence and a final ceramic layer, i.e. an outermost ceramic layer, precise control of color location may be achieved for the light emitted by the light-emitting semiconductor device.

Further advantages, advantageous embodiments and further developments are revealed by the following exemplary embodiments described below in conjunction with the figures, in which:

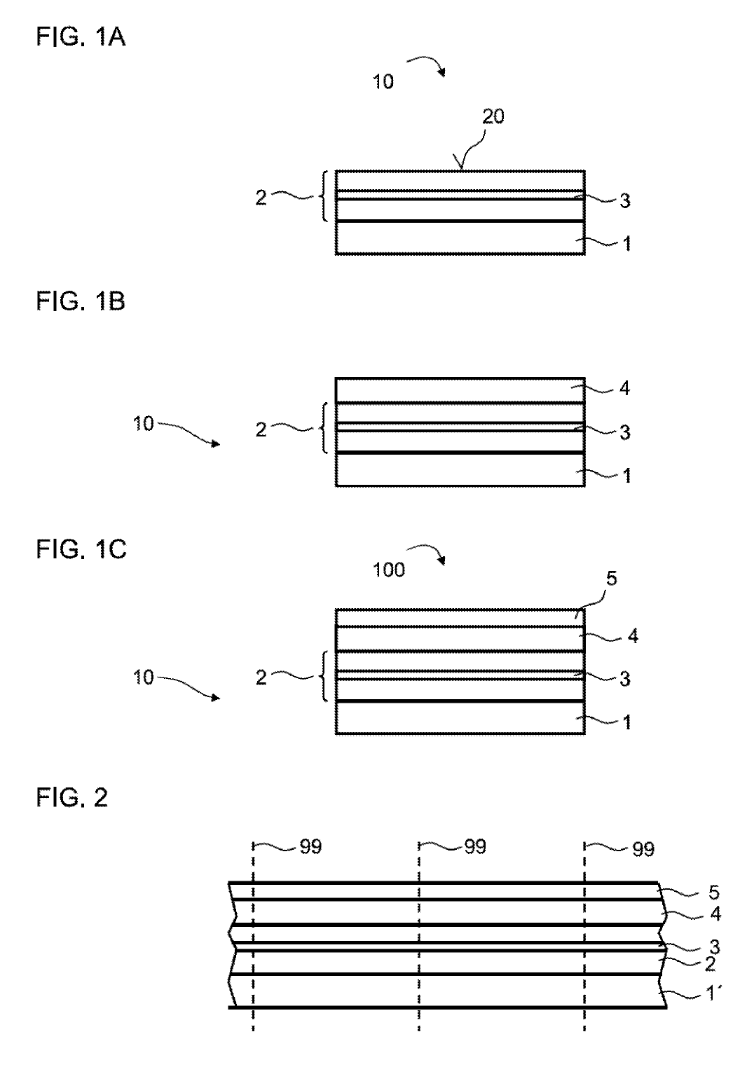

FIGS. 1A to 1C are schematic representations of a method for producing a light-emitting semiconductor device according to an exemplary embodiment,

FIG. 2 is a schematic representation of a method step of a method for producing a light-emitting semiconductor device according to a further exemplary embodiment,

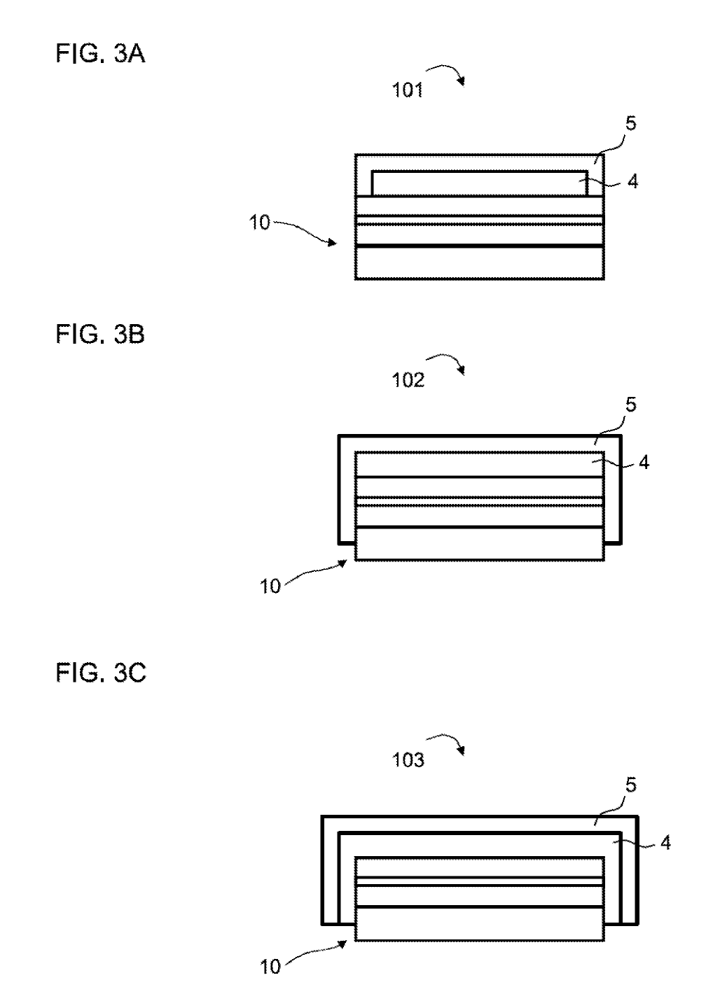

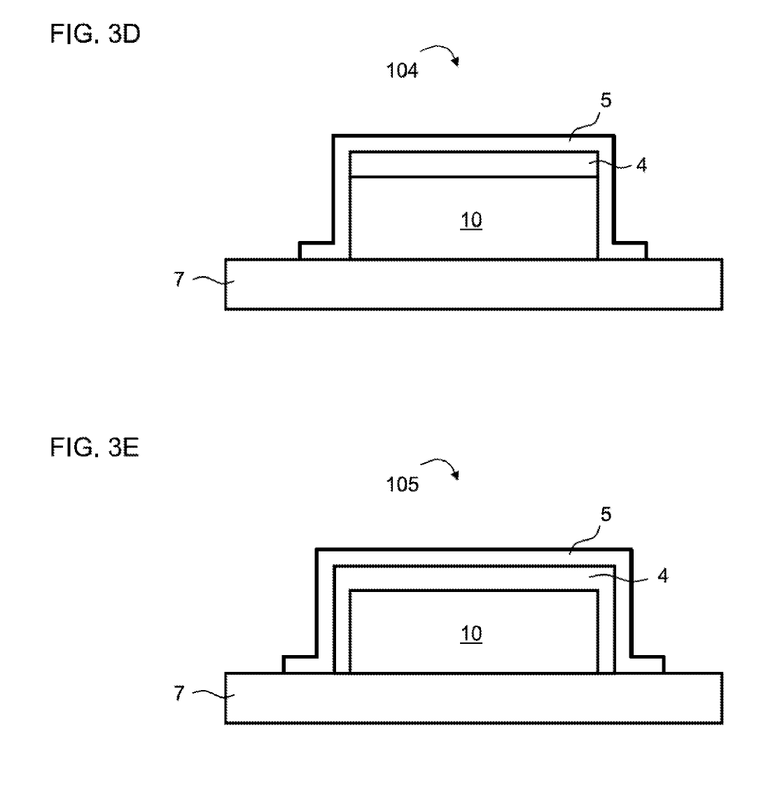

FIGS. 3A to 6 are schematic representations of light-emitting semiconductor devices according to further exemplary embodiments.

In the exemplary embodiments and figures, elements that are identical, of identical type or act identically may be provided in each case with the same reference signs. The illustrated elements and their size relationships among one another should not be regarded as true to scale; rather, individual elements such as, for example, layers, structural parts, components and regions may be illustrated with an exaggerated size in order to enable better illustration and/or in order to afford a better understanding.

FIGS. 1A to 1C show a method for producing a light-emitting semiconductor device 100 according to one exemplary embodiment.

In a first method step according to FIG. 1A, a light-emitting semiconductor layer sequence 2 is provided. In the exemplary embodiment shown, the semiconductor layer sequence 2 is part of a light-emitting semiconductor chip 10, which comprises a substrate 1 and the semiconductor layer sequence 2 thereon.

The semiconductor layer sequence 2 comprises an active layer 3, which is suitable for generating light when in operation which may be emitted via a light outcoupling surface 20 arranged on the side of the semiconductor layer sequence 2 remote from the substrate 1. The individual layers of the semiconductor layer sequence 2 other than the active layer 3, for example n- and p-doped semiconductor layers such as for instance buffer layers, cladding layers, semiconductor contact layers, barrier layers, current spreading layers and/or current limiting layers, as well as electrical connection layers such as for instance electrode layers or electrical contact elements are not shown so as to simplify the illustration.

In the exemplary embodiment shown, the semiconductor layer sequence 2 and in particular the active layer 3 comprises a nitride compound semiconductor material system, such that in operation ultraviolet to green light, preferably blue to green light, may be emitted. Alternatively or in addition, the semiconductor layer sequence 2 may also comprise another semiconductor material mentioned in the general part.

The substrate 1 may for example comprise a growth substrate, for example of sapphire, to which the semiconductor layer sequence 2 is applied by epitaxial growth, for example by metal-organic vapor deposition (MOVPE) or molecular beam epitaxy (MBE). A multiplicity of light-emitting semiconductor chips 10 may be formed by singulation from a substrate wafer provided with the semiconductor layer sequence 2.

Alternatively, it is also possible for the substrate 1 to be formed by a carrier substrate, onto which the semiconductor layer sequence 2 grown on a growth substrate is transferred. The growth substrate may then be removed at least in part or wholly to form a thin-film light-emitting diode chip described above in the general part.

The growth and optionally the transfer of the grown semiconductor layer sequence 2 onto a carrier substrate preferably takes place at wafer level prior to subsequent singulation.

The light-emitting semiconductor chip 10 may be provided for the further method steps on an auxiliary carrier, for example a plastics film. Alternatively, it is also possible for the semiconductor chip 10 to be provided mounted on a carrier, which together with the semiconductor chip 10 may form a “package”. The carrier may for example comprise or be a plastics housing, a printed circuit board, a metal core printed circuit board or a ceramic substrate and be provided with electrical terminals for electrical contacting of the semiconductor chip 10. It may moreover also be possible, for the further method steps, for a plurality of semiconductor chips 10 to be arranged on an auxiliary carrier or mounted on a carrier and for the method steps described hereinafter to be performed for the plurality of semiconductor chips 10.

In a further method step according to FIG. 1B, a wavelength conversion layer 4 is applied to the semiconductor layer sequence 2, which layer 4 comprises a wavelength conversion material for at least partial conversion of the light generated in the active layer 3 when the finished light-emitting semiconductor device 100 is in operation.

Application of the wavelength conversion layer 4 may proceed for example by sedimentation. To this end, a sedimentation solution is provided which contains the wavelength conversion material which may be embodied according to the description in the general part. For improved adhesion of the wavelength conversion material particles in the wavelength conversion layer, a binder may for example also be added to the sedimentation solution, as described above in the general part. The sedimentation solution is applied to the semiconductor layer sequence 2, in the exemplary embodiment shown in particular on the light outcoupling surface 20. By removing the liquid constituents of the sedimentation solution, for example by evaporation or vaporization, and deposition of the wavelength conversion material contained in the sedimentation solution, the wavelength conversion layer 4 is formed.

Alternatively, a scattering method may be selected for application of the wavelength conversion material. Furthermore, it is also possible for the wavelength conversion material for forming the wavelength conversion layer 4 to be applied by means of electrophoretic deposition.

To increase the robustness of the wavelength conversion layer 4, it may also be possible for the wavelength conversion material to be pretreated, for example by washing with phosphoric acid to form hydrogen bonds in the wavelength conversion layer 4. Using the described method, the wavelength conversion layer may in particular be substantially pulverulent, which means that the wavelength conversion material does not form a contiguous amalgamation and thus does not form a continuous, solid wavelength conversion layer.

In a further method step according to FIG. 1C, a ceramic layer 5 is applied to the wavelength conversion layer 4 by means of aerosol deposition. In particular, a transparent ceramic material is selected as the ceramic material for the ceramic layer, which material where possible has a refractive index adapted to the wavelength conversion layer to allow maximally efficient conversion and outcoupling of light in the finished light-emitting semiconductor device 100. It may moreover be advantageous for the material of the ceramic layer 5 to be adapted with regard to the coefficient of thermal expansion to the material of the wavelength conversion layer 4 and/or to the material of the semiconductor chip 10, i.e. for example to the material of the semiconductor layer sequence 2 and/or of the substrate 1, in order to prevent stresses between the wavelength conversion layer 4 and the ceramic layer 5 in the event of the light-emitting semiconductor device 100 undergoing operational temperature rises.

The surface of the ceramic layer 5 may furthermore be produced with a desired roughness and/or surface structure, whereby improved light outcoupling may be achieved in subsequent operation.

To produce the ceramic layer by means of the aerosol deposition method, a powder with a pulverulent ceramic material is provided as described above in the general part and fed to a gas stream, such that the aerosol formed by the gas and the powder is applied in an aerosol jet by means of a nozzle onto the surface to be coated, which in the exemplary embodiment shown is formed by the wavelength conversion layer 4. As a result of the high kinetic energy of the pulverulent ceramic material in the aerosol jet, on impact on the surface or on particles already applied to the surface, the particles contained in the aerosol undergo consolidation, i.e. “clumping together”. The aerosol jet may be movable relative to the surface to be coated by movement of the nozzle and/or of the semiconductor layer sequence with the wavelength conversion layer, such that the ceramic layer may be formed flat on the wavelength conversion layer 4. In particular, the ceramic layer 5 may be free of further, non-ceramic constituents.

The ceramic layer 5 may comprise one of the materials described above in the general part, particularly preferably Al₂O₃, AlN, SiN, SiO₂, TiO₂, ZrO₂ or a combination or mixture thereof and be formed with a thickness as above in the general part, for example with a thickness in the range of a few tens of micrometers, i.e. in the range from approximately 20 μm to approximately 100 μm.

As a result of impact of the particles of the aerosol on the pulverulent wavelength conversion layer 4, it may even be possible, at least at one surface of the wavelength conversion layer 4, to arrive at at least partial intermixing of the ceramic material of the ceramic layer 5 and of the at least one wavelength conversion material of the wavelength conversion layer 4, such that at least in sub-regions the ceramic material of the ceramic layer 5 may form a matrix material for the wavelength conversion material.

It may moreover also be possible for the wavelength conversion layer 4 to be provided and applied as ceramic plates. Application of the ceramic plate formed by the wavelength conversion material or the wavelength conversion material and a ceramic matrix material may, as shown in FIG. 1B and in FIG. 1C, take place before application of the ceramic layer 5. Alternatively, it is also possible firstly to cover the ceramic plate forming the wavelength conversion layer 4 with the ceramic layer 5 by means of aerosol deposition and then to apply the ceramic plate together with the ceramic layer 5 to the semiconductor layer sequence 2.

It may moreover be possible subsequently to heat the ceramic layer 5 again after application. In such a heat treatment process, the ceramic layer 5 may be heated to a temperature which may be as high as the sintering temperature of the ceramic material used, preferably to a temperature markedly below the sintering temperature.

By means of the described method, a light-emitting semiconductor device 100 may thus be provided which, on the light-emitting semiconductor layer sequence 2 with the active layer 3, may comprise a wavelength conversion layer 4 with at least one wavelength conversion material and a ceramic layer 5 thereover, wherein the ceramic layer 5 is applied by means of aerosol deposition. As described above in the general part, the wavelength conversion layer 4 may be protected from external influences, for example from moisture but also from mechanical influences, by the direct application of the ceramic layer 5 on the wavelength conversion layer 4. Furthermore, improved adhesion of the wavelength conversion material to the semiconductor layer sequence 2 may be achieved.

As an alternative to coating of an already singulated semiconductor chip 10 with the wavelength conversion layer 4 and the ceramic layer 5, at least production of the wavelength conversion layer 4 or indeed production of the wavelength conversion layer 4 and production of the ceramic layer 5 may take place at wafer level prior to singulation. FIG. 2 in this respect shows a semiconductor layer sequence 2 on a substrate wafer 1′, onto which the wavelength conversion layer 4 and the ceramic layer 5 are applied. The substrate wafer 1′ may be a growth substrate wafer or a carrier substrate wafer. Then the layer arrangement shown may be singulated along the indicated singulation lines 99 into semiconductor chips with the wavelength conversion layer 4 and ceramic layer 5.

FIGS. 3A to 6 show further exemplary embodiments which may be produced using the above-described methods. The following description therefore substantially relates to the differences and modifications relative to the preceding exemplary embodiments.

The following exemplary embodiments each show semiconductor chips 10 which comprise the semiconductor layer sequence 2 with the active layer 3 shown in FIG. 1A on the substrate 1, but without these reference signs being shown explicitly in the following figures for the sake of clarity. In particular the exemplary embodiments shown in FIGS. 3A to 3C and 4 to 6 may moreover be produced both at chip level and also at wafer level according to the methods of FIGS. 1A to 1C and FIG. 2.

FIG. 3A shows an exemplary embodiment of a light-emitting semiconductor device 101, in which the wavelength conversion layer 4 is covered with the ceramic layer 5 on all surfaces which are exposed after application of said wavelength conversion layer 4 to the semiconductor layer sequence 2. In this way, protection may be provided on all sides by the ceramic layer 5.

To achieve maximally hermetic deposition of the ceramic layer 5, the latter should follow the contour of the substrate to be coated as well as possible. In particular at steps and edges hermetic encapsulation requires conformal deposition of the ceramic material. Since the aerosol deposition method is a highly directional coating method, in which the jet with the pulverulent ceramic material should impact as perpendicularly as possible on the surface to be coated, shading may readily occur at steps, which may lead to a lower layer thickness, above all at side faces. Such reduced lateral layer growth may however jeopardize the reliably impervious enclosure of contours.

The ceramic layer 5 shown in the exemplary embodiment of FIG. 3A is therefore produced in a method in which the direction of the aerosol jet is varied over a wide range of angles of incidence, measured relative to the main plane of extension of the wavelength conversion layer 4. In this way, coating may take place at all or at least over a very wide range of all occurring local surface normals, such that the ceramic layer 5 may be applied in a maximally conformal layer with a substantially constant layer thickness, measured at the surface normals in each case to be determined locally. With particularly pronounced steps, the jet may here even be guided almost tangentially to the main plane of extension of the wavelength conversion layer 4.

Such application of the ceramic material may be achieved for example in that the spray nozzle is accordingly inclined continuously to the various angles or in that the object to be coated is held at different angles in the deposition jet. In the case of a very widely fanned out jet, the object to be coated may to this end be placed rotatably on a rotating hemisphere, whereby uniform deposition can be achieved. Instead of this planetary motion, the object to be coated may also be operated as a gyroscope with precession. In the case in particular of a narrower jet, which must be more finely scanned, the object to be coated may also be inclined purposefully in such a way as is required by the part of the surface to be coated at any given time. This type of control makes it possible to apply the ceramic layer 5 in a particularly economical manner, since the proportion of powder which impinges on the surface at unfavorable angles and does not contribute to layer growth is kept small. To this end, it may be helpful always to hold the surface to be coated in a somewhat eucentric position by lateral displacement.

FIG. 3B shows a further exemplary embodiment of a light-emitting semiconductor device 102 in which, in comparison with the exemplary embodiment of FIG. 3A, the ceramic layer 5 is applied not only to the wavelength conversion layer 4, but also to side faces of the semiconductor chip 10. The side faces of the semiconductor chip 10 may be formed, as is shown for example in FIG. 3B, by side faces of the semiconductor layer sequence 2 and of the substrate 1. Alternatively, it is also possible for the ceramic layer 5 to be applied, in addition to the wavelength conversion layer 4, solely to side faces of the semiconductor layer sequence.

FIG. 3C shows a further exemplary embodiment of a light-emitting semiconductor layer sequence 103, in which both the wavelength conversion layer 4 and the ceramic layer 5 are applied, in addition to the light outcoupling surface 20, to side faces of the semiconductor chip 10.

FIG. 3D shows a further exemplary embodiment of a light-emitting semiconductor device 104, in which a carrier 7, as already mentioned above, is provided, on which the semiconductor chip 10 is applied. In this exemplary embodiment, the ceramic layer 5 extends over the wavelength conversion layer 4 and over side faces of the semiconductor chip 10 to a surface region of the mounting face of the carrier 7, on which the semiconductor chip 10 is arranged and mounted.

FIG. 3E shows a further exemplary embodiment of a light-emitting semiconductor device 105, in which, in addition to the ceramic layer 5, the wavelength conversion layer 4 also extends as far as the carrier 7.

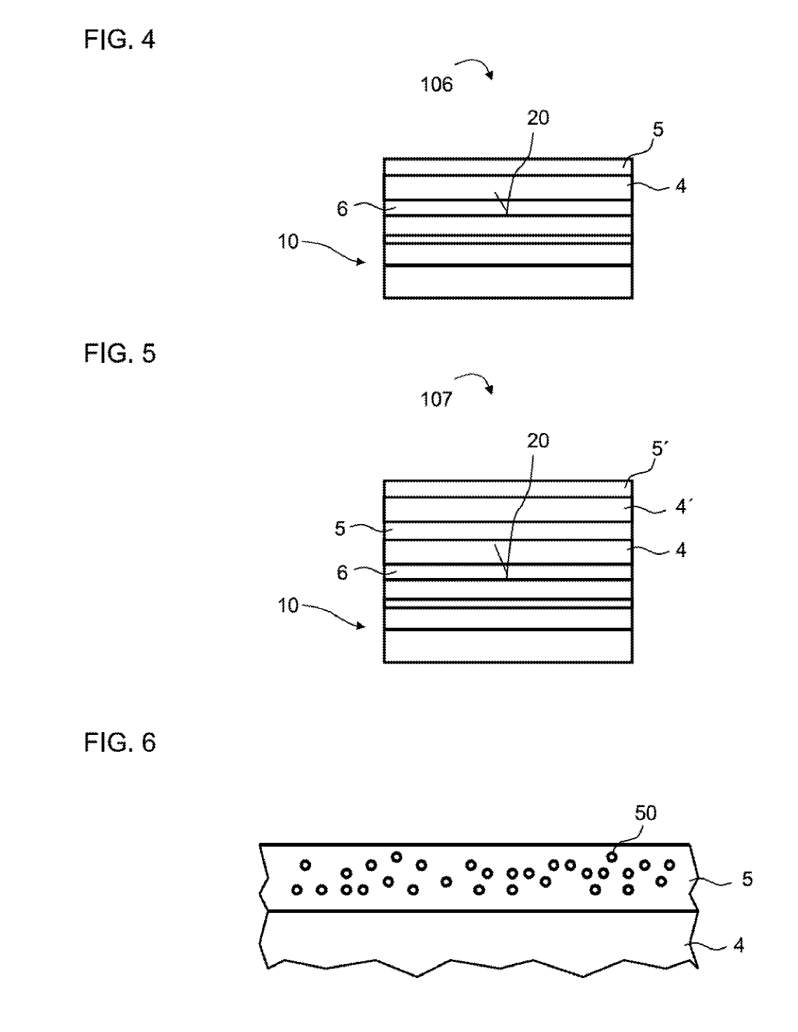

FIG. 4 shows a further exemplary embodiment of a light-emitting semiconductor device 106 in which, prior to application of the wavelength conversion layer 4 onto the semiconductor layer sequence 2, a further transparent ceramic layer 6 is applied by means of an aerosol deposition method. The further ceramic layer 6 may in particular lead to an improvement in the adhesion of the wavelength conversion layer 4 to the semiconductor layer sequence 2.

FIG. 5 shows a further exemplary embodiment of a light-emitting semiconductor device 107, which additionally comprises a further wavelength conversion layer 4′ and a further ceramic layer 5′ applied by means of aerosol deposition over the ceramic layer 5. Further wavelength conversion layers and/or ceramic layers may moreover also be present. As a result of such sequential coating of the semiconductor layer sequence, precise color control is for example possible during the production process, whereby the color location of the light emitted by the light-emitting semiconductor device when in operation may be optimized.

FIG. 6 shows a further exemplary embodiment of a ceramic layer 5 on a wavelength conversion layer 4, wherein the ceramic layer 5 comprises light scattering particles 50 which have a different refractive index from the ceramic material of the ceramic layer 5. The light scattering particles may for example be embodied as described above in the general part. Alternatively or in addition, it is also possible for light scattering particles 50 to be present in the wavelength conversion layer 4, as described in the general part.

The exemplary embodiments shown in the figures may also be combined together, according to further exemplary embodiments, even if such combinations have not been explicitly described in conjunction with the figures. Furthermore, the exemplary embodiments shown in the figures may alternatively or in addition comprise features described further above in the general part.

The description made with reference to exemplary embodiments does not restrict the invention to these embodiments. Rather, the invention encompasses any novel feature and any combination of features, including in particular any combination of features in the claims, even if this feature or this combination is not itself explicitly indicated in the claims or exemplary embodiments.

1. Light-emitting semiconductor device comprising
a light-emitting semiconductor layer sequence with an active layer which is configured to emit light when the semiconductor device is in operation,
a wavelength conversion layer with at least one wavelength conversion material on the semiconductor layer sequence and
a ceramic layer on the wavelength conversion layer, which is applied by means of aerosol deposition.

2. Semiconductor device according to claim 1, wherein the ceramic layer is formed from a transparent ceramic material.

3. Semiconductor device according to claim 2, wherein the ceramic layer comprises an oxide, nitride or oxynitride with aluminum, silicon, titanium or zirconium.

4. Semiconductor device according to claim 1, wherein a further transparent ceramic layer is applied to the semiconductor layer sequence by means of an aerosol deposition method, on which further layer the wavelength conversion layer is applied.

5. Semiconductor device according to claim 1, wherein a plurality of ceramic layers and/or a plurality of wavelength conversion layers are applied alternately on one another.

6. Semiconductor device according to claim 1, wherein the wavelength conversion material is present in powder form between the semiconductor layer sequence and the ceramic layer.

7. Semiconductor device according to claim 1, wherein the ceramic layer and/or the wavelength conversion layer contains light scattering particles.

8. Method for producing a light-emitting semiconductor device, in which
a light-emitting semiconductor layer sequence is provided with an active layer which is configured to emit light when the semiconductor device is in operation,
a wavelength conversion layer with at least one wavelength conversion material is applied to the semiconductor layer sequence and
a ceramic layer is applied to the wavelength conversion layer by means of an aerosol deposition method.

9. Method according to claim 8, in which the wavelength conversion material is applied in powder form.

10. Method according to claim 9, in which the wavelength conversion material is washed in phosphoric acid prior to application.

11. Method according to claim 8, in which the wavelength conversion material is applied by sedimentation, scattering or by electrophoretic deposition.

12. Method according to claim 11, in which a sedimentation solution comprising the wavelength conversion material and a binder is provided and is applied to form the wavelength conversion layer.

13. Method according to claim 8, in which the wavelength conversion layer is provided and applied as a ceramic plate.

14. Method according to claim 13, in which the ceramic layer is applied to the ceramic plate before the ceramic plate is applied to the semiconductor layer sequence.

15. Method according to claim 13, in which the ceramic layer is applied to the ceramic plate already applied to the semiconductor layer sequence.

16. Semiconductor device according to claim 2, wherein the ceramic layer comprises at least one or more of Al₂O₃, AN, SiN, SiO₂, TiO₂ and ZrO₂

17. Method for producing a light-emitting semiconductor device, in which
a light-emitting semiconductor layer sequence is provided with an active layer which is configured to emit light when the semiconductor device is in operation,
a wavelength conversion layer with at least one wavelength conversion material is applied to the semiconductor layer sequence in powder form, by sedimentation, by scattering, by electrophoretic deposition or as a ceramic plate, and
a ceramic layer is applied to the wavelength conversion layer by means of an aerosol deposition method.
